(19) United States
(12) Patent Application Publication
(10) Pub. No.: US 2006/0079064 A1
(43) Pub. Date: Apr. 13, 2006

(54) Fabrication method for a trench capacitor having an insulation collar which on one side is electrically connected to a substrate via a buried contact, in particular for a semiconductor memory cell, and corresponding trench capacitor

(76) Inventor: Harald Seidl, Poring (DE)

Correspondence Address: JENKINS, WILSON & TAYLOR, P. A., 3100 TOWER BLVD, SUITE 1200, DURHAM, NC, 27707, US

(21) Appl. No.: 11/229,868

(22) Filed: Sep. 19, 2005

(30) Foreign Application Priority Data
Oct. 12, 2004 (DE) 102004049667.6

(51) Int. Cl. H01L 21/20

(52) U.S. Cl. 438/386

(57) ABSTRACT

Fabrication method for a trench capacitor having an insulation collar which on one side is electrically connected to a substrate via a buried contact, in particular for a semiconductor memory cell, and corresponding trench capacitor

The present invention provides a fabrication method for a trench capacitor having an insulation collar (10; 10a, 10b) in a substrate (1), which on one side is electrically connected to the substrate (1) via a buried contact (15a, 15b), comprising the steps of: providing a trench (5) in the substrate (1) using a hard mask (2, 3) with a corresponding mask opening; providing a capacitor dielectric (30) in the lower and middle trench regions, the insulation collar (10) in the middle and upper trench regions and an electrically conductive filling (20) at least as far as the top side of the insulation collar (10), with the top side of the insulation collar (10) being at a distance from the top side (OS) of the substrate (1); causing the electrically conductive filling (20) to recede to below the top side of the insulation collar (10); on one side, forming an insulation region (IS; IS1, IS2) with respect to the substrate (1) above the insulation collar (10); on the other side, forming a terminal region (KS; KS1, KS2) with respect to the substrate (1) above the insulation collar (10); providing an interface layer (100) of a transition metal nitride on the terminal region (KS; KS1, KS2); and forming the buried contact (15a, 15b) by depositing and etching back a conductive filling (70). The invention also provides a corresponding trench capacitor.

Fabrication method for a trench capacitor having an insulation collar which on one side is electrically connected to a substrate via a buried contact, in particular for a semiconductor memory cell, and corresponding trench capacitor

The present invention relates to a fabrication method for a trench capacitor having an insulation collar which on one side is electrically connected to a substrate via a buried contact, in particular for a semiconductor memory cell, and to a corresponding trench capacitor.

Although in principle it can be applied to any desired integrated circuits, the present invention, as well as the problems on which it is based, are explained with reference to integrated memory circuits produced using silicon technology.

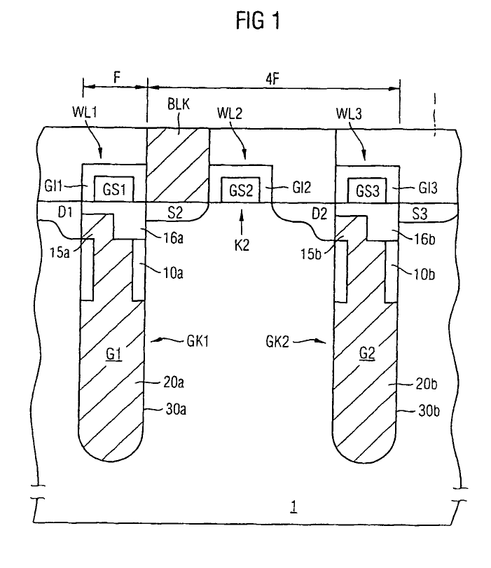

FIG. 1 shows a diagrammatic sectional illustration of a semiconductor memory cell with a trench capacitor and a planar select transistor connected to it.

In FIG. 1, reference number 1 denotes a silicon semiconductor substrate. Trench capacitors GK1, GK2, which have trenches G1, G2 whereof electrically conductive fillings 20a, 20b form first capacitor electrodes, are provided in the semiconductor substrate 1. The conductive fillings 20a, 20b are insulated from the semiconductor substrate 1, which for its part forms the second capacitor electrodes (optionally in the form of a buried plate, not shown), by a dielectric 30a, 30b in the lower and middle trench regions.

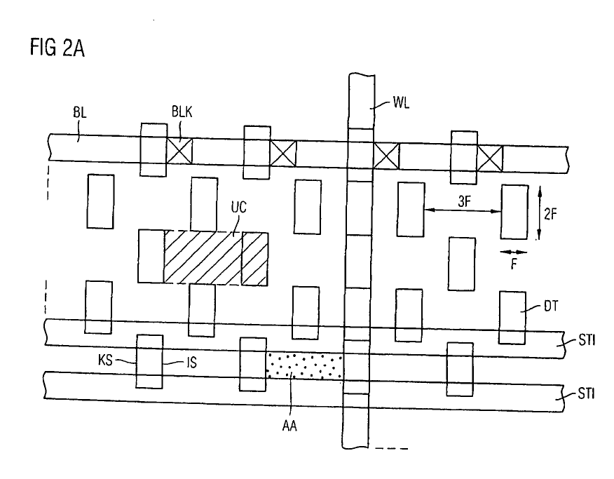

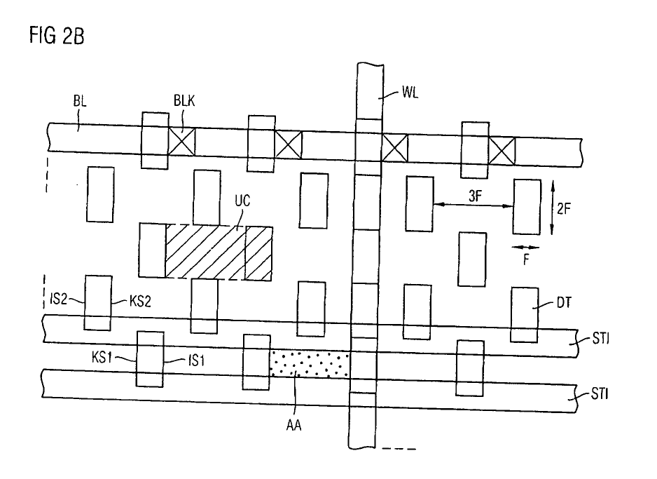

Encircling insulation collars 10a, 10b are provided in the middle and upper regions of the trenches G1, G2, and above these insulation collars are arranged buried contacts 15a, 15b, which are in electrical contact with the conductive fillings 20a, 20b and the adjoining semiconductor substrate 1. The buried contacts 15a, 15b are only connected to the semiconductor substrate 1 on one side (cf. FIGS. 2a, 2b). Insulation regions 16a, 16b insulate the other side of the substrate from the buried contacts 15a, 15b or insulate the buried contacts 15a, 15b from the top side of the trenches G1, G2.

This allows a very high packing density of the trench capacitors GK1, GK2 and of the associated select transistors, which will now be explained. This explanation refers predominantly to the select transistor which belongs to the trench capacitor GK2, since only the drain region D1 or the source region S3 of adjacent select transistors is included in the drawing. The select transistor belonging to the trench capacitor GK2 has a source region S2, a channel region K2 and a drain region D2. The source region S2 is connected via a bit line contact BLK to a bit line (not shown) arranged above an insulation layer I. On one side, the drain region D2 is connected to the buried contact 15b. A word line WL2, which includes a gate stack GS2 and a gate insulator GI2 surrounding the gate stack, runs above the channel region K2. For the select transistor of the trench capacitor GK2, the word line WL2 is an active word line.

Word lines WL1 comprising gate stack GS1 and gate insulator GI1 and word line WL3 comprising gate stack GS3 and gate insulator GI3, which for the select transistor of the trench capacitor GK2 are passive word lines, run parallel and adjacent to the word line WL2. These word lines WL1, WL3 are used to drive select transistors which are offset in the third dimension with respect to the sectional illustration shown.

FIG. 1 clearly reveals the fact that this type of single-sided connection of the buried contact allows the trenches and the adjacent source regions or drain regions of corresponding select transistors to be arranged directly next to one another. This means that the length of a memory cell can be just 4F and the width just 2F, where F is the minimum feature size (cf. FIGS. 2a, b).

FIG. 2A shows a plan view of a memory cell array comprising memory cells as shown in FIG. 1 in a first possible arrangement.

Reference designation DT in FIG. 2A denotes trenches which are arranged in rows with a distance of 3F between them and in columns with a distance of 2F between them. Adjacent rows are offset by 2F with respect to one another. UC in FIG. 2A denotes the area of a unit cell, which amounts to 4F×2F=8F². STI denotes isolation trenches which are arranged at a distance of 1F from one another in the row direction and isolate adjacent active areas from one another. Bit lines BL run in the row direction, likewise at a distance of 1F from one another, whereas the word lines run in the column direction at a distance of 1F from one another. In this arrangement example, all the trenches DT have a contact region KS of the buried contact to the substrate on the left-hand side and an insulation region IS on the right-hand side (regions 15a, b and 16a, b respectively, in FIG. 1).

FIG. 2B shows a plan view of a memory cell array comprising memory cells as shown in FIG. 1 in a second possible arrangement.

In this second possible arrangement, the rows of trenches have alternating terminal regions or insulation regions of the buried contacts. For example, in the bottom row in FIG. 2B, the buried contacts are each provided with a contact region KS1 on the left-hand side and with an insulation region IS1 on the right-hand side. By contrast, in the row above, all the trenches DT are each provided with an insulation region IS2 on the left-hand side and with a contact region KS2 on the right-hand side. This arrangement alternates in the column direction.

For DRAM memory devices with trench capacitors in sub-100 nm technologies, the resistance of the trench and of the buried contact form a major contribution to the total RC delay and therefore determine the speed of the DRAM. The series resistance in the trench increases dramatically as a result of the relatively low conductivity and the pinch-off caused by an overlay shift in the STI etch.

This problem has been tackled by the introduction of highly arsenic-doped polysilicon, improving the overlay between the active areas and the trench, introducing a self-aligned fabrication of a buried contact with connection on one side and thinning the nitrided contact location of the buried contact. Nevertheless, the Si₃N₄ interface increases the series resistance significantly, since the charge carriers have to tunnel through the Si₃N₄ interface. In particular, Si₃N₄ has a band gap of approx. 5.3 eV and a band offset with respect to the conduction band of Si of approx. 2.4 eV. Therefore, the tunnelling current through the Si₃N₄ is very low and the resistance of this material very high.

The object of the present invention is to provide an improved fabrication method for a trench capacitor with a lower RC delay which is connected on one side.

According to the invention, this object is achieved by the fabrication method described in claim 1 and the trench capacitor described in claim 8.

The core concept of the present invention consists in creating a process in which it is possible to do without the Si₃N₄ interface, since an interface with a lower band gap and a lower band offset is used. Consequently, the tunnelling current is very high and the resistance very low.

The subclaims give advantageous refinements and improvements to the subject matter of the invention.

According to one preferred refinement, after the conductive filling has been etched back, an insulation cap is provided in the upper trench region at least as far as the top side of the substrate.

According to another preferred refinement, the filling is provided as far as the top side of the insulation collar, then a nitride liner layer is deposited, and then the trench is completely filled with a filling material, followed by an STI trench production process and removal of the filling material.

According to a further preferred refinement, after the filling material has been removed, spacers are formed at the trench walls above the insulation collar, and the spacer lying above the terminal region is removed, with the spacer lying above the insulation region being masked using a silicon liner.

According to a further preferred refinement, the interface layer is deposited by means of the ALD process.

According to a further preferred refinement, the interface layer consists of Hf₃N₄ or Zr₃N₄.

According to a further preferred refinement, the interface layer is from 0.5-2 nm thick.

An exemplary embodiment of the invention is illustrated in the drawings and explained in more detail in the description which follows. In the drawings:

FIG. 1 shows a diagrammatic sectional illustration through a semiconductor memory cell with a trench capacitor and a planar select transistor connected to it;

FIGS. 2A, B show respective plan views of a memory cell array with memory cells as shown in FIG. 1 in the form of first and second possible arrangements; and

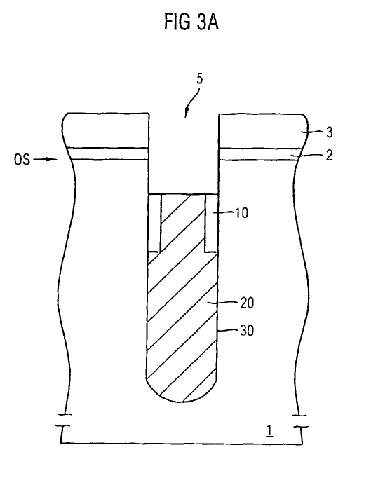

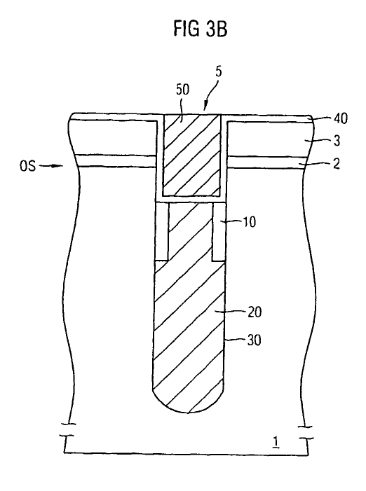

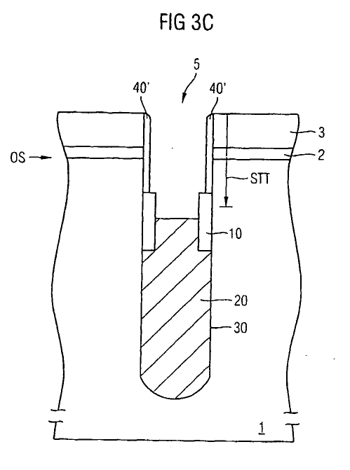

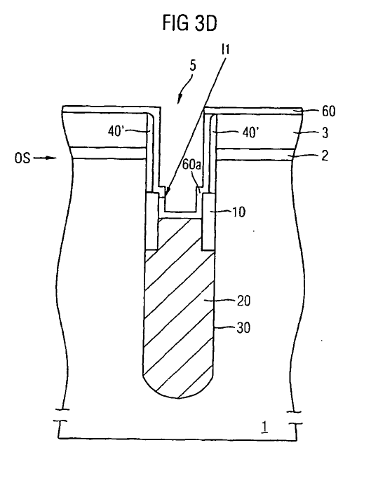

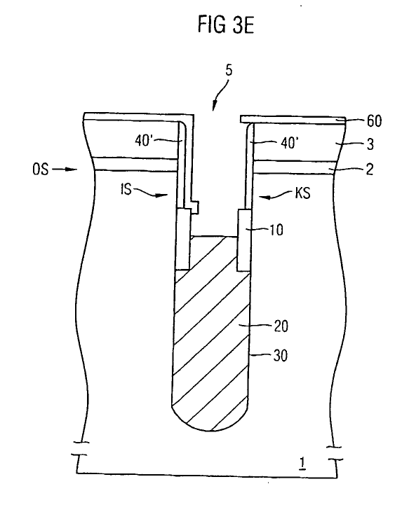

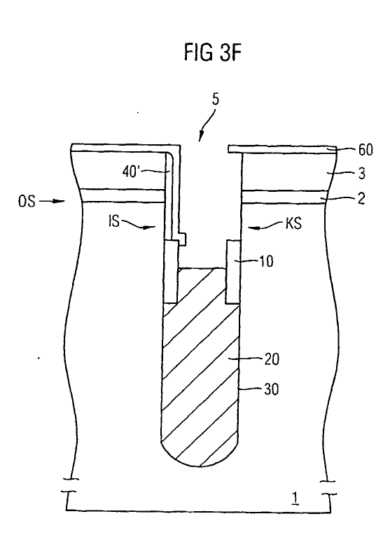

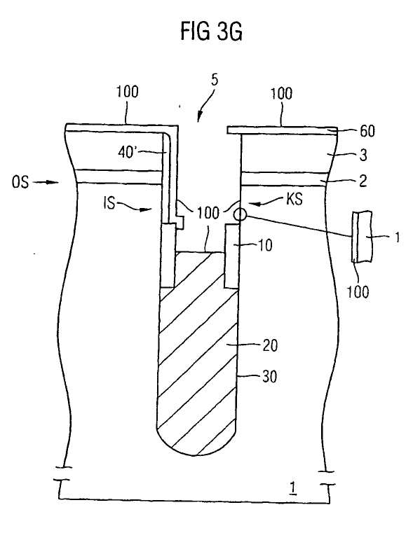

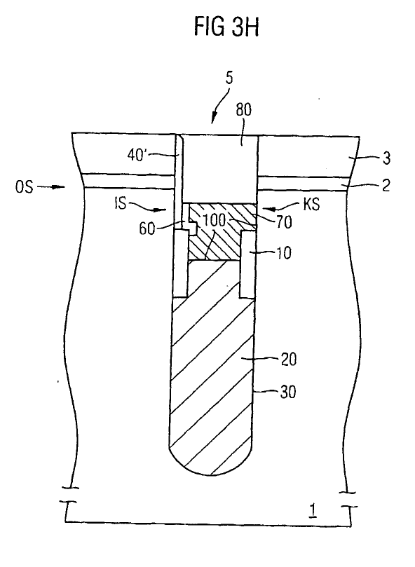

FIGS. 3A-H diagrammatically depict successive method stages involved in a fabrication method as an embodiment of the present invention.

In the figures, identical reference designations denote identical or functionally equivalent components.

In the embodiments described below, the production of the planar select transistors is not described, for the sake of clarity, and only the formation of the buried contact of the trench capacitor which is connected on one side is expounded upon in detail. The steps involved in producing the planar select transistors, unless expressly stated otherwise, are the same as those used in the prior art.

FIGS. 3A-F diagrammatically depict successive method stages involved in a fabrication method as a first embodiment of the present invention.

In FIG. 3A, reference number 5 denotes a trench which is provided in the silicon semiconductor substrate 1. A hard mask comprising a pad oxide layer 2 and a pad nitride layer 3 is provided on the top side OS of the semiconductor substrate 1. A dielectric 30, which insulates an electrically conductive filling 20 with respect to the surrounding semiconductor substrate 1, is provided in the lower and middle regions of the trench 5. An encircling insulation collar 10 is provided in the upper and middle regions of the trench 5 and has been caused to recede into the trench 5 to approximately the same height as the conductive filling 20. One example of a material which can be used for the insulation collar 10 is silicon oxide, and one example of a material which can be used for the electrically conductive filling 20 is polysilicon. However, it is, of course, also conceivable to use other combinations of materials.

In accordance with FIG. 3B, first of all a liner layer 40 is deposited over the structure shown in FIG. 3A, the liner layer consisting of silicon nitride or silicone nitride/silicon oxide, e.g. thermal SiO₂ and LPCVD Si₃N₄.

Then, the trench 5 is closed up again by a polysilicon filling 50, for example by deposition followed by chemical mechanical polishing.

In a subsequent process step, which is not illustrated in the Figures, a hard mask is then formed over the structure, corresponding to STI trenches that are to be formed, lying in parallel planes in front of and behind the plane of the drawing, followed by the etching and filling of the STI trenches (high-temperature process). Then, the hard mask for the STI trench formation is removed again.

The purpose of this preferred high-temperature step is to prevent the high-temperature step from being able to influence the buried contact which is to be formed at a later stage.

Then, continuing with reference to FIG. 3C, in which STT denotes the STI trench depth, the polysilicon filling 50 is removed by a wet etch, and an anisotropic spacer etch is carried out on the liner layer 40 to form spacers 40′. As can be seen from FIG. 3C, during the etchback of the polysilicon filling, the trench polysilicon filling 20 is also etched back to below the top side of the insulation collar 10, so that the STI trench depth STR is between the top side of the insulation collar 10 and the top side of the trench polysilicon filling 20.

Then, referring to FIG. 3D, conformal deposition of an amorphous silicon liner 60 is carried out over the resulting structure, into which boron ions are implanted by means of an oblique implantation I1; reference designation 60a denotes a region shadowed from the implantation. The region 60a of the silicon liner 60 which has been shadowed from the implantation has a higher etching rate with respect to an NH₄OH etch, which is carried out as the next process step.

Referring now to FIG. 3E, an NH₄OH etch leads to it being possible for the region 60a to be removed selectively with respect to the remaining, implanted region of the silicon liner 60.

A subsequent process step involves carrying out a selective etch by means of H₃PO₄ on the uncovered region, located on the right-hand side of the figure, of the nitride spacer 40′, in order to uncover the subsequent contact region KS of the buried contact, as shown in FIG. 3F.

Then in accordance with FIG. 3G, an ALD deposition of a 0.5-2 nm thick Hf₃N₄ layer 100 is carried out, which serves to form an interface at the top side of the trench polysilicon filling 20 and in the subsequent contact region KS of the substrate 1.

Hf₃N₄ has a band gap of 1.8 eV and is eminently suitable as an interface for preventing grain boundaries which could subsequently grow into the silicon substrate 1.

This is followed, referring to FIG. 3H, by metal deposition, for example of TiN or of silicon, to form a conductive filling 70 in the contact region KS on the Hf₃N₄ interface layer 100.

Then, the conductive filling 70 is etched back to below the top side OS of the substrate 1 but above the uncovered region of the insulation collar 10.

Finally, the trench 5 is filled in a known way with an insulation cap 80 consisting, for example, of silicon oxide.

Although the present invention has been described above on the basis of a preferred exemplary embodiment, it is not restricted to this particular embodiment, but rather can be modified in numerous ways.

In particular, the choice of layer materials is merely an example and these materials can be varied in numerous ways.

Although Hf₃N₄ was used as interface layer in the above example, it is also possible to use other materials with a low band gap and a low band offset, e.g. Zr₃N₄, as the interface layer.

### LIST OF DESIGNATIONS

1 Si semiconductor substrate
OS Top side
2 Pad oxide
3 Pad nitride
5 Trench
10, 10a, 10b Insulation collar
20, 20a, 20b Conductive filling (e.g. polysilicon)
15a, 15b Buried contact
16a, 16b Insulation region
G1, G2 Trench
GK1, GK2 Trench capacitor
30, 30a, 30b Capacitor dielectric
S1, S2, S3 Source region
D1, D2 Drain region
K2 Channel region
WL, WL1, WL2, WL3 Word line
GS1, GS2, GS3 Gate stack
GI1, GI2, GI3 Gate insulator
I Insulation layer
F Minimum feature size
BLK Bit line contact
BL Bit line
DT Trench
AA Active area
STI Isolation region (shallow trench isolation)
UC Area unit cell
KS, KS1, KS2 Contact region
IS, IS1, IS2 Insulation region
40 Silicon nitride/oxide liner
40′ Spacer formed from 40
50 Polysilicon filling
60 Silicon liner
60a Shadowed region
70 Conductive filling
80 Insulation cap
STT STI trench depth
100 Hf₃N₄ interface layer

1. Fabrication method for a trench capacitor having an insulation collar (10; 10a, 10b) in a substrate (1), which on one side is electrically connected to the substrate (1) via a buried contact (15a, 15b), in particular for a semiconductor memory cell having a planar select transistor which is provided in the substrate (1) and is connected via the buried contact (15a, 15b), comprising the steps of:
providing a trench (5) in the substrate (1) using a hard mask (2, 3) with a corresponding mask opening;
providing a capacitor dielectric (30) in the lower and middle trench regions, the insulation collar (10) in the middle and upper trench regions and an electrically conductive filling (20) at least as far as the top side of the insulation collar (10), with the top side of the insulation collar (10) being at a distance from the top side (OS) of the substrate (1);
causing the electrically conductive filling (20) to recede to below the top side of the insulation collar (10);
on one side, forming an insulation region (IS; IS1, IS2) with respect to the substrate (1) above the insulation collar (10);
on the other side, forming a terminal region (KS; KS1, KS2) with respect to the substrate (1) above the insulation collar (10);
providing an interface layer (100) of a transition metal nitride on the terminal region (KS; KS1, KS2); and
forming the buried contact (15a, 15b) by depositing and etching back a conductive filling (70).

2. Method according to claim 1, characterized in that after the conductive filling (70) has been etched back, an insulation cap (80) is provided in the upper trench region at least as far as the top side (OS) of the substrate (1).

3. Method according to claim 1, characterized in that the filling (20) is provided as far as the top side of the insulation collar (10), then a nitride liner layer (40) is deposited, and then the trench (5) is completely filled with a filling material (50), followed by an STI trench production process and removal of the filling material.

4. Method according to claim 3, characterized in that after the filling material (50) has been removed, spacers (40′) are formed at the trench walls above the insulation collar (10), and the spacer (40′) lying above the terminal region (KS) is removed, with the spacer (40′) lying above the insulation region being masked using a silicon liner (60).

5. Method according to one of the preceding claims, characterized in that the interface layer (100) is deposited by means of the ALD process.

6. Method according to one of the preceding claims, characterized in that the interface layer (100) consists of Hf₃N₄ or Zr₃N₄.

7. Method according to claim 6, characterized in that the interface layer (100) is from 0.5-2 nm thick.

8. Trench capacitor having an insulation collar (10; 10a, 10b) in a substrate (1), which on one side is electrically connected to the substrate (1) via a buried contact (15a, 15b), in particular for a semiconductor memory cell having a planar select transistor which is provided in the substrate (1) and is connected via the buried contact (15a, 15b), the trench capacitor having:
a trench (5) in the substrate (1);
a capacitor dielectric (30) in the lower and middle trench regions, the insulation collar (10) in the middle and upper trench regions and an electrically conductive filling (20) at least as far as the top side of the insulation collar (10), with the top side of the insulation collar (10) being at a distance from the top side (OS) of the substrate (1);
on one side, an insulation region (IS; IS1, IS2) with respect to the substrate (1) above the insulation collar (10);
on the other side, a terminal region (KS; KS1, KS2) with respect to the substrate (1) above the insulation collar (10);
an interface layer (100) of a transition metal nitride on the terminal region (KS; KS1, KS2); and
the buried contact (15a, 15b) as a conductive filling (70).

9. Trench capacitor according to claim 8, characterized in that the interface layer (100) consists of Hf₃N₄ or Zr₃N₄.

10. Trench capacitor according to claim 8 or 9, characterized in that the interface layer (100) is from 0.5-2 nm thick.
